(19) United States
(12) Patent Application Publication
(10) Pub. No.: US 2015/0294694 A1
(43) Pub. Date: Oct. 15, 2015

(54) AREA EFFICIENT LAYOUT WITH PARTIAL TRANSISTORS

(71) Applicant: QUALCOMM Incorporated, San Diego, CA (US)

(72) Inventors: Changho JUNG, San Diego, CA (US); Tony Chung Yiu KWOK, San Diego, CA (US); Nishith Nitin DESAI, San Diego, CA (US)

(73) Assignee: QUALCOMM Incorporated, San Diego, CA (US)

(21) Appl. No.: 14/251,495

(22) Filed: Apr. 11, 2014

(51) Int. Cl. G11C 5/06; G11C 7/10

(52) U.S. Cl. CPC G11C 5/063; G11C 7/10

(57) ABSTRACT

A CMOS apparatus includes a first transistor having a first transistor gate, a second transistor having a second transistor gate, a partial transistor having a gate and only one of a drain or a source. The CMOS apparatus further includes a gate interconnect connecting the first transistor gate to the second transistor gate through the gate of the partial transistor. The CMOS apparatus may be a bit cell. A write word enable line may include the gate interconnect, and the first and second transistors may enable write bit lines to the bit cell.

### BACKGROUND

1. Field

The present disclosure relates generally to a layout construction, and more particularly, to an area efficient layout with partial transistors.

2. Background

A bit cell is an integrated circuit that may be implemented with digital logic. An application-specific integrated circuit (ASIC), such as a system-on-a-chip (SoC) device, may contain thousands to millions of bit cells. Reducing a size/area footprint of ASICs is beneficial. Accordingly, there is a need for reducing the size/area footprint of bit cells.

### SUMMARY

In an aspect of the disclosure, a complementary metal oxide semiconductor (CMOS) apparatus includes a first transistor having a first transistor gate, a second transistor having a second transistor gate, and a partial transistor having a gate and only one of a drain or a source. The CMOS apparatus further includes a gate interconnect connecting the first transistor gate to the second transistor gate through the gate of the partial transistor. The apparatus may be a bit cell. A write word enable line may include the gate interconnect, and the first and second transistors may enable write bit lines to the bit cell. The CMOS apparatus may further include a first inverter having a first inverter output and a first inverter input, and a second inverter having a second inverter input and a second inverter output. The first inverter output may be connected to the second inverter input. The first inverter input may be connected to the second inverter output. The first inverter output and the second inverter input may be connected to the one of the drain or the source of the partial transistor.

### BRIEF DESCRIPTION OF THE DRAWINGS

FIG. 1 is a diagram illustrating an exemplary layout of a CMOS apparatus.

FIG. 2 is a circuit diagram of a multiport bit cell.

FIG. 3 is a diagram illustrating an exemplary layout of a multiport bit cell.

FIG. 4 is an exemplary circuit diagram of a multiport bit cell corresponding to the exemplary multiport bit cell layout of FIG. 3.

FIG. 5 is a flow chart of a method of operating a CMOS apparatus.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

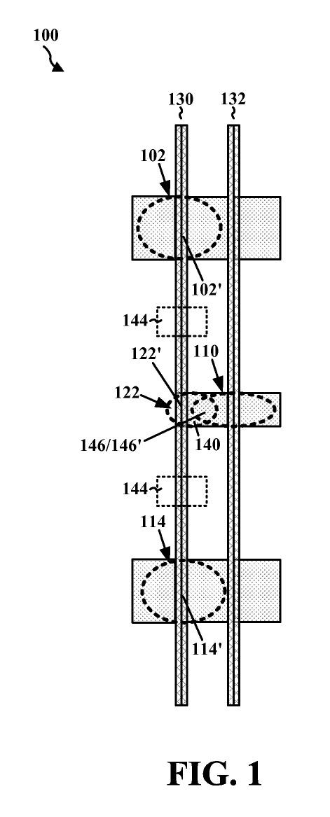

FIG. 1 is a diagram 100 illustrating an exemplary layout of a CMOS apparatus.

As shown in FIG. 1, the CMOS apparatus includes transistors 102, 110, and 114. The transistors 102 and 114 may be n-type metal oxide semiconductor (nMOS) transistors, and the transistor 110 may be a p-type metal oxide semiconductor (pMOS) transistor. Gate interconnects 130 and 132 extend (vertically as illustrated) across the bit cell. The gate interconnects may also be referred to as POLY interconnects. The gate interconnects may be formed of metal, such as in a 20 nm or 16 nm process technology. However, in other process technologies, the gate interconnects may be entirely polysilicon or may be polysilicon with a metal top layer. An active region 140 of the transistor 110 extends under the gate interconnect 130. In particular, a drain 146′ of the transistor 110 extends under the gate interconnect 130. A partial transistor 122 (also referred to as a “half transistor”) is formed where the active region 140 of the transistor 110 extends under the gate interconnect 130. The partial transistor 122 has only one of a drain or a source 146. (The p-type region 146 adjacent the gate 122′ of the partial transistor 122 may be considered a drain or a source.) The drain/source 146 of the partial transistor 122 is the same region as the drain 146′ of the transistor 110. If the gates of the transistors 102 and 114 are to be connected together, in order to avoid the negative effects of the partial transistor 122, cuts 144 are formed in the gate interconnect 130 to isolate the transistors 102 and 114 from the partial transistor 122 and the gates of the transistors 102 and 114 are connected together through vias and higher layer metal interconnects.

In an exemplary layout of the CMOS apparatus, in order to reduce routing within the bit cell and a size/area footprint of the bit cell, the gates of the transistors 102 and 114 may be connected together through the gate interconnect 130 via the gate 122′ without the cuts 144 in the gate interconnect 130, which also forms the gates of the transistors 102 and 114 and the partial transistor 122. Connecting the gates of the transistors 102 and 114 together through the gate interconnect 130 via the gate 122′ of the partial transistor 122 introduces a coupling capacitance to the gate interconnect 130. The coupling capacitance slows down signals on the gate interconnect 130. However, in some applications the introduction of such coupling capacitance may be tolerated.

Referring again to FIG. 1, the exemplary CMOS apparatus includes a first transistor 102 with a first transistor gate 102′ and a second transistor 114 with a second transistor gate 114′. The apparatus further includes a partial transistor 122 with a gate 122′ and only one of a drain or a source 146. The CMOS apparatus further includes a gate interconnect 130 connecting the first transistor gate 102′ to the second transistor gate 114′ through the gate 122′ of the partial transistor 122.

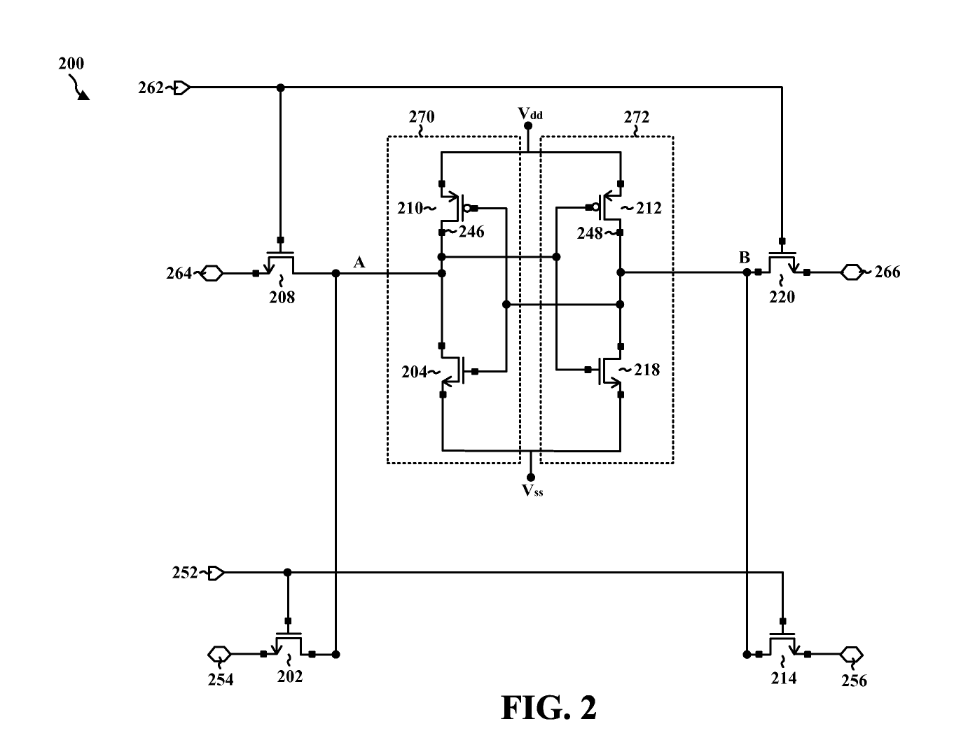

FIG. 2 is a circuit diagram 200 of a multiport bit cell. A first write word enable line 252 turns on the transistors 202 and 214. A source of the transistor 202 is coupled to a first write bit line 254 and a drain of the transistor 202 is coupled to node A. A source of the transistor 214 is coupled to a first write inverted bit line 256 and a drain of the transistor 214 is coupled to node B. A second write word enable line 262 turns on the transistors 208 and 220. A source of the transistor 208 is coupled to a second write bit line 264 and a drain of the transistor 208 is coupled to node A. A source of the transistor 220 is coupled to a second write inverted bit line 266 and a drain of the transistor 220 is coupled to node B. Node B is coupled to an input of a first inverter 270 including pMOS transistor 210 and nMOS transistor 204 connected in series. An output 246 of the first inverter 270 is coupled to node A. Node A is coupled to an input of a second inverter 272 including pMOS transistor 212 and nMOS transistor 218 connected in series. An output 248 of the second inverter 272 is coupled to node B. Sources of the pMOS transistors 210 and 212 are coupled together to a voltage source V_{dd}. Sources of the nMOS transistors 204 and 218 are coupled together to a voltage source Vₛₛ.

When the first write word enable line 252 is enabled (with a high voltage), the first write bit line 254 inputs a bit (0 or 1) to the second inverter 272 and the first write inverted bit line 256 inputs the inverted bit to the first inverter 270. The first and second inverters 270, 272 store the inputted bit. Similarly, when the second write word enable line 262 is enabled (with a high voltage), the second write bit line 264 inputs a bit (0 or 1) to the second inverter 272 and the second write inverted bit line 266 inputs the inverted bit to the first inverter 270. The first and second inverters 270, 272 store the inputted bit.

Referring again to FIG. 1 and FIG. 2, in exemplary embodiments the gate interconnect 130 that interconnects the transistors 102 and 114 and the partial transistor 122 and forms the gates 102′, 114′, and 122′ is or is part of the first write word enable line 252 or the second write word enable line 262. Accordingly, the first write word enable line 252 or the second write word enable line 262 is routed via the interconnect 130.

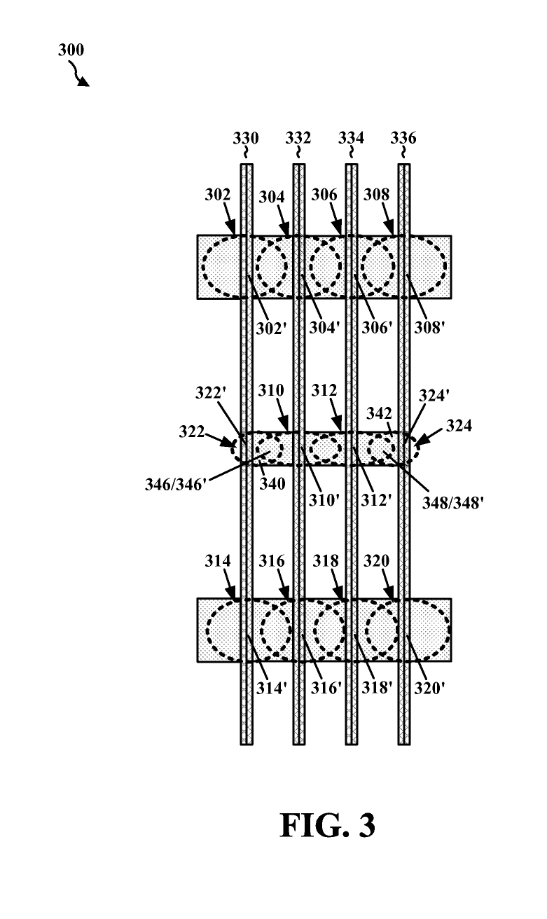

FIG. 3 is a diagram 300 illustrating an exemplary layout of a multiport bit cell.

FIG. 3 illustrates only transistors and gate interconnects without all of the cuts in the gate interconnects or use of higher layer metal interconnects. As shown in FIG. 3, the CMOS apparatus includes transistors 302, 310, and 314. The transistors 302 and 314 may be nMOS transistors and the transistor 310 may be a pMOS transistor. The transistors 302, 310, and 314 have gates 302′, 310′, and 314′, respectively. Gate interconnects 330 and 332 extend (vertically as illustrated) across the bit cell. An active region 340 of the transistor 310 extends under the gate interconnect 330. In particular, a drain 346′ of the transistor 310 extends under the gate interconnect 330. A partial transistor 322 (also referred to as a “half transistor”) is formed where the active region 340 of the transistor 310 extends under the gate interconnect 330. The partial transistor 322 has only one of a drain or a source 346. (The p-type region 346 adjacent the gate 322′ of the partial transistor 322 may be considered a drain or a source.) The drain/source 346 of the partial transistor 322 is the same region as the drain 346′ of the transistor 310. The gates 302′ and 314′ of the transistors 302 and 314, respectively, are connected together via the gate 322′ through the gate interconnect 330, which also forms the gates of the transistors 302 and 314 and the partial transistor 322. Accordingly, the gates 302′ and 314′ are connected to the gate 322′ of the partial transistor 322 by the gate interconnect 330. As discussed supra, connecting the transistors 302 and 314 together through the gate interconnect 330 via the gate 322′ of the partial transistor 322 introduces a coupling capacitance to the gate interconnect 330 (which slows down signals on the gate interconnect 330), but in some applications the coupling capacitance may be tolerated.

The CMOS apparatus further includes transistors 304, 306, 308, 312, 316, 318, and 320. The transistors 304, 306, 308, 316, 318, and 320 may be nMOS transistors and the transistor 312 may be a pMOS transistor. The transistors 304, 306, 308, 312, 316, 318, and 320 have gates 304′, 306′, 308′, 312′, 316′, 318′, and 320′, respectively. The nMOS transistor 306 may be biased off (e.g., by connecting Vₛₛ to the gate 306′ of the transistor 306) in order to isolate the nMOS transistors 304 and 308 from each other. In addition, the nMOS transistor 316 may be biased off (e.g., by connecting Vₛₛ to the gate 316′ of the transistor 316) in order to isolate the nMOS transistors 314 and 318 from each other. Gate interconnects 334 and 336 extend (vertically as illustrated) across the bit cell. An active region 342 of the transistor 312 extends under the gate interconnect 336. In particular, a drain 348′ of the transistor 312 extends under the gate interconnect 336. A partial transistor 324 (also referred to as a “half transistor”) is formed where the active region 342 of the transistor 312 extends under the gate interconnect 336. The partial transistor 324 has only one of a drain or a source 348. (The p-type region 348 adjacent the gate 324′ of the partial transistor 324 may be considered a drain or a source.) The drain/source 348 of the partial transistor 324 is the same region as the drain 348′ of the transistor 312. The gates 308′ and 320′ of the transistors 308 and 320, respectively, are connected together via the gate 324′ through the gate interconnect 336, which also forms the gates of the transistors 308 and 320 and the partial transistor 324. Accordingly, the gates 308′ and 320′ are connected to the gate 324′ of the partial transistor 324 by the gate interconnect 336. As discussed supra, connecting the transistors 308 and 320 together through the gate interconnect 336 via the gate 324′ of the partial transistor 324 introduces a coupling capacitance to the gate interconnect 336 (which slows down signals on the gate interconnect 336), but in some applications the coupling capacitance may be tolerated.

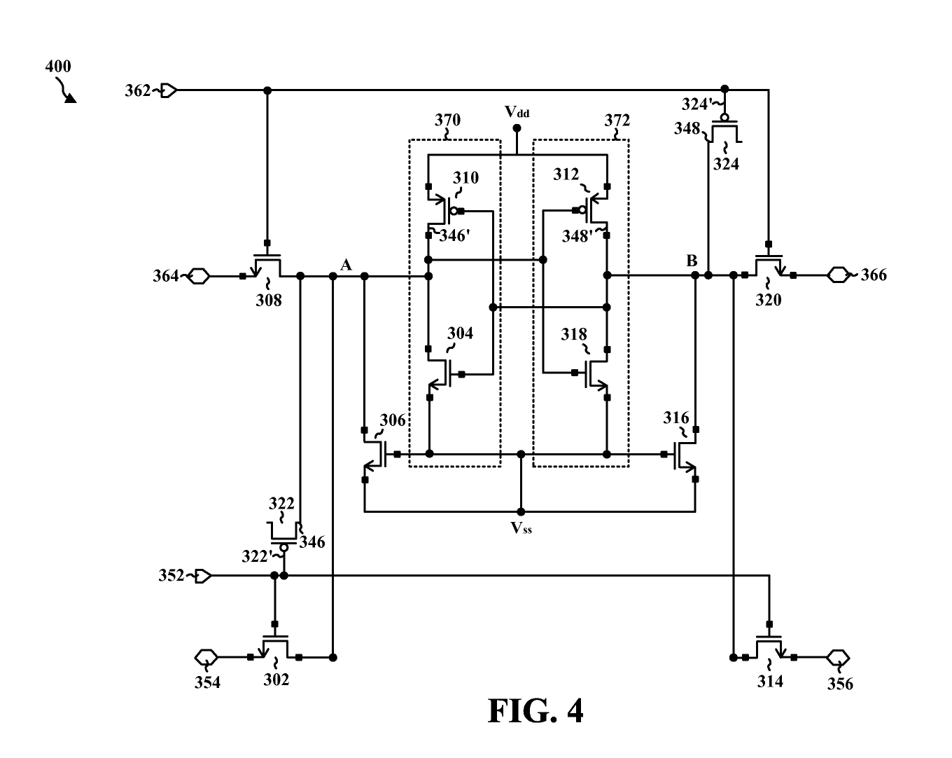

FIG. 4 is an exemplary circuit diagram 400 of a multiport bit cell corresponding to the exemplary multiport bit cell layout of FIG. 3. A first write word enable line 352 turns on the transistors 302 and 314. The write word enable line 352 may be the gate interconnect 330 or include the gate interconnect 330 (see FIG. 3). A source of the transistor 302 is coupled to a first write bit line 354 and a drain of the transistor 302 is coupled to node A. A source of the transistor 314 is coupled to a first write inverted bit line 356 and a drain of the transistor 314 is coupled to node B. A second write word enable line 362 turns on the transistors 308 and 320. The write word enable line 362 may be the gate interconnect 336 or include the gate interconnect 336 (see FIG. 3). A source of the transistor 308 is coupled to a second write bit line 364 and a drain of the transistor 308 is coupled to node A. A source of the transistor 320 is coupled to a second write inverted bit line 366 and a drain of the transistor 320 is coupled to node B. Node B is coupled to an input of a first inverter 370 including pMOS transistor 310 and nMOS transistor 304 connected in series. An output of the first inverter 370 is coupled to node A. Node A is coupled to an input of a second inverter 372 including pMOS transistor 312 and nMOS transistor 318 connected in series. An output of the second inverter 372 is coupled to node B. In particular, the drain 346′ of the pMOS transistor 310 is coupled to node A and the drain 348′ of the pMOS transistor 312 is coupled to node B. Sources of the pMOS transistors 310 and 312 are coupled together to a voltage source V_{dd}. Sources of the nMOS transistors 304 and 318 are coupled together to a voltage source Vₛₛ. The nMOS transistor 306 is biased off in order to isolate the nMOS transistors 304 and 308 from each other (see FIG. 3). The nMOS transistor 316 is biased off in order to isolate the nMOS transistors 314 and 318 from each other (see FIG. 3). The partial transistor 322 has a gate 322′ connected to the first write word enable line 352 and a drain/source 346 connected to node A. The partial transistor 324 has a gate 324′ connected to the second write word enable line 362 and a drain/source 348 connected to node B. The partial transistors 322, 324 are partial pMOS transistors.

When the first write word enable line 352 is enabled (with a high voltage), the first write bit line 354 inputs a bit (0 or 1) to the second inverter 372 and the first write inverted bit line 356 inputs the inverted bit to the first inverter 370. The first and second inverters 370, 372 store the inputted bit. Similarly, when the second write word enable line 362 is enabled (with a high voltage), the second write bit line 364 inputs a bit (0 or 1) to the second inverter 372 and the second write inverted bit line 366 inputs the inverted bit to the first inverter 370. The first and second inverters 370, 372 store the inputted bit. The partial transistors 322, 324 introduce a coupling capacitance to the gate interconnects 330, 336, respectively. However, the negative effects of the coupling capacitance may be tolerated within the illustrated multiport bit cell in order to obtain the benefits of reduced routing within the bit cell and a reduced size/area footprint of the bit cell as a result of the reduced routing.

Referring again to FIG. 3 and FIG. 4, a CMOS apparatus includes a first transistor 302 having a first transistor gate 302′, a second transistor 314 having a second transistor gate 314′, and a partial transistor 322 having a gate 322′ and only one of a drain or a source 346. The apparatus further includes a gate interconnect 330 connecting the first transistor gate 302′ to the second transistor gate 314′ through the gate 322′ of the partial transistor 322. The apparatus may be a bit cell, such as the multiport bit cell illustrated in FIG. 4. A write word enable line 352 or a portion of the write word enable line 352 may be the gate interconnect 330. Accordingly, the write word enable line 352 may include the gate interconnect 330. The first and second transistors 302, 314 may enable write bit lines 354 and 356, respectively, to the bit cell.

The apparatus may further include a first inverter 370 having a first inverter output (node A) and a first inverter input (node B). The apparatus may further include a second inverter 372 having a second inverter input (node A) and a second inverter output (node B). The first inverter output (node A) may be connected to the second inverter input (node A). The first inverter input (node B) may be connected to the second inverter output (node B). The first inverter output (node A) and the second inverter input (node A) may be connected to the drain/source 346 of the partial transistor 322.

In one configuration, the first inverter 370 includes a third transistor 310 and a fourth transistor 304. The third transistor 310 has a third transistor gate 310′, a third transistor drain 346′, and a third transistor source. The fourth transistor 304 has a fourth transistor gate 304′, a fourth transistor drain, and a fourth transistor source. The third transistor gate 310′ is connected to the fourth transistor gate 304′. The third transistor drain 346′ is connected to the fourth transistor drain. The first inverter input (node B) is at the third transistor gate 310′ and the fourth transistor gate 304′. The first inverter output (node A) is at the third transistor drain 346′ and the fourth transistor drain. The third transistor drain 346′ is the drain/source 346 of the partial transistor 322.

In one configuration, the third transistor 310 is a pMOS transistor, the fourth transistor 304 is an nMOS transistor, and the drain/source 346 of the partial transistor 322 is a p-type region. In one configuration, the apparatus further includes a fifth transistor 308 having a fifth transistor gate 308′, a sixth transistor 320 having a sixth transistor gate 320′, and a second partial transistor 324 having a gate 324′ and only one of a drain or a source 348. The apparatus further includes a second gate interconnect 336 connecting the fifth transistor gate 308′ to the sixth transistor gate 320′ through the gate 324′ of the second partial transistor 324. The apparatus may be a bit cell. A write word enable line 362 or a portion of the write word enable line 362 may be the second gate interconnect 336. Accordingly, the write word enable line 362 may include the second gate interconnect 336. The fifth and sixth transistors 308, 320 may enable write bit lines 364 and 366, respectively, to the bit cell. The first inverter input (node B) and the second inverter output (node B) may be connected to the drain/source 348 of the second partial transistor 324.

In one configuration, the second inverter 372 includes a seventh transistor 312 and an eighth transistor 318. The seventh transistor 312 has a seventh transistor gate 312′, a seventh transistor drain 348′, and a seventh transistor source. The eighth transistor 318 has an eighth transistor gate 318′, an eighth transistor drain, and an eighth transistor source. The seventh transistor gate 312′ is connected to the eighth transistor gate 318′. The seventh transistor drain 348′ is connected to the eighth transistor drain. The third transistor source is coupled to the seventh transistor source, both of which may be coupled to V_{dd}. The fourth transistor source is coupled to the eighth transistor source, both of which may be coupled to Vₛₛ. The second inverter input (node A) is at the seventh transistor gate 312′ and the eighth transistor gate 318′. The second inverter output (node B) is at the seventh transistor drain 348′ and the eighth transistor drain. The seventh transistor drain 348′ is the drain/source 348 of the second partial transistor 324. In one configuration, the seventh transistor 312 is a pMOS transistor, the eighth transistor 318 is an nMOS transistor, and the drain/source 348 of the second partial transistor 324 is a p-type region.

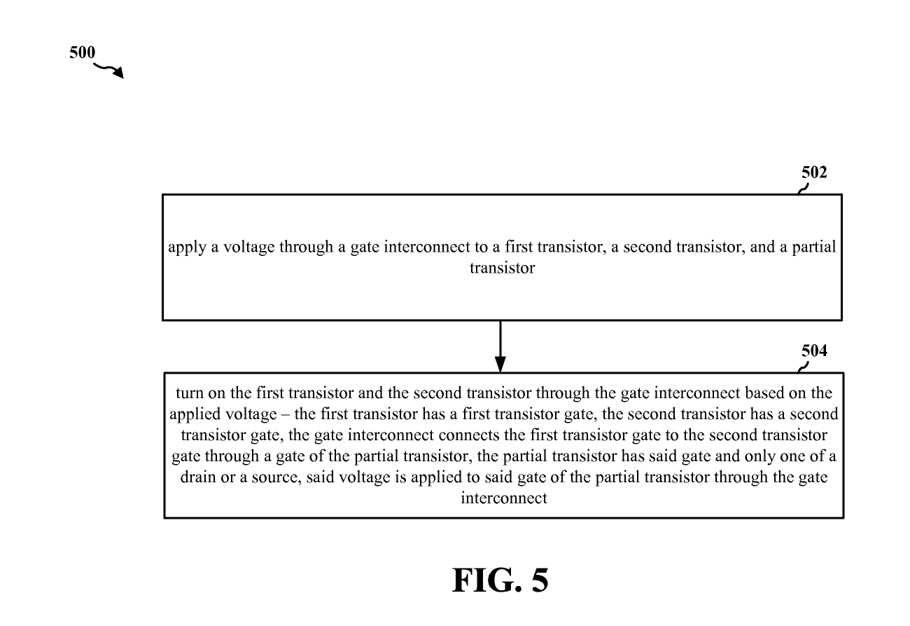

FIG. 5 is a flow chart 500 of a method of operating a CMOS apparatus. In step 502, a voltage is applied through a gate interconnect to a first transistor, a second transistor, and a partial transistor. In step 504, the first transistor and the second transistor are turned on through the gate interconnect based on the applied voltage. The first transistor has a first transistor gate. The second transistor has a second transistor gate. The gate interconnect connects the first transistor gate to the second transistor gate through a gate of the partial transistor. The partial transistor has said gate and only one of a drain or a source. The voltage is applied to the gate of the partial transistor through the gate interconnect.

In one configuration, the apparatus is a bit cell, a write word enable line includes the gate interconnect, and the first and second transistors enable write bit lines to the bit cell when the first and second transistors are turned on. In one configuration, the apparatus includes a first inverter and a second inverter. The first inverter has a first inverter output and a first inverter input. The second inverter has a second inverter input and a second inverter output. The first inverter output is connected to the second inverter input. The first inverter input is connected to the second inverter output. The first inverter output and the second inverter input are connected to the one of the drain or the source of the partial transistor. In one configuration, the first inverter includes a third transistor and a fourth transistor; the third transistor has a third transistor gate, a third transistor drain, and a third transistor source; the fourth transistor has a fourth transistor gate, a fourth transistor drain, and a fourth transistor source; the third transistor gate is connected to the fourth transistor gate; the third transistor drain is connected to the fourth transistor drain; the first inverter input is at the third transistor gate and the fourth transistor gate; the first inverter output is at the third transistor drain and the fourth transistor drain; and the third transistor drain is the one of the drain or the source of the partial transistor. In one configuration, the third transistor is a pMOS transistor, the fourth transistor is an nMOS transistor, and the one of the drain or the source of the partial transistor is a p-type region.

In one configuration, a CMOS apparatus includes means for applying a voltage through a gate interconnect to a first transistor, a second transistor, and a partial transistor. The apparatus further includes means for turning on the first transistor and the second transistor through the gate interconnect based on the applied voltage. The first transistor has a first transistor gate. The second transistor has a second transistor gate. The gate interconnect connects the first transistor gate to the second transistor gate through a gate of the partial transistor. The partial transistor has said gate and only one of a drain or a source. The voltage is applied to the gate of the partial transistor through the gate interconnect. The means for applying a voltage through a gate interconnect to a first transistor, a second transistor, and a partial transistor includes the gate interconnect that connects gates of the first transistor, second transistor, and partial transistor together. The means for applying a voltage through a gate interconnect to a first transistor, a second transistor, and a partial transistor further includes the first transistor, the second transistor, and the partial transistor. The means for turning on the first transistor and the second transistor through the gate interconnect based on the applied voltage includes the gate interconnect, the first transistor, and the second transistor. As discussed supra, the first transistor has a first transistor gate, the second transistor has a second transistor gate, and the partial transistor has a gate and only one of a drain or a source. The gate interconnect connects the first transistor gate to the second transistor gate through the gate of the partial transistor.

As provided supra, a gate interconnect may extend to connect and to form the gates of two transistors and a partial transistor. The partial transistor introduces a coupling capacitance in the path for turning on the two transistors. However, the negative effects of the coupling capacitance may be tolerated in some applications, such as for example, in the write word enable lines of the provided multiport bit cell, in order to obtain benefits of reduced routing and a reduced size/area footprint.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A complementary metal oxide semiconductor (CMOS) apparatus, comprising:
a first transistor having a first transistor gate;
a second transistor having a second transistor gate;
a partial transistor having a gate and only one of a drain or a source; and
a gate interconnect connecting the first transistor gate to the second transistor gate through the gate of the partial transistor.

2. The apparatus of claim 1, wherein the apparatus is a bit cell, a write word enable line comprises the gate interconnect, and the first and second transistors enable write bit lines to the bit cell.

3. The apparatus of claim 1, further comprising:
a first inverter having a first inverter output and a first inverter input; and
a second inverter having a second inverter input and a second inverter output, the first inverter output being connected to the second inverter input, the first inverter input being connected to the second inverter output,
wherein the first inverter output and the second inverter input are connected to said one of the drain or the source of the partial transistor.

4. The apparatus of claim 3, wherein the first inverter comprises a third transistor and a fourth transistor; the third transistor has a third transistor gate, a third transistor drain, and a third transistor source; the fourth transistor has a fourth transistor gate, a fourth transistor drain, and a fourth transistor source; the third transistor gate is connected to the fourth transistor gate; the third transistor drain is connected to the fourth transistor drain; the first inverter input is at the third transistor gate and the fourth transistor gate; the first inverter output is at the third transistor drain and the fourth transistor drain; and the third transistor drain is said one of the drain or the source of the partial transistor.

5. The apparatus of claim 4, wherein the third transistor is a p-type metal oxide semiconductor (pMOS) transistor, the fourth transistor is an n-type metal oxide semiconductor (nMOS) transistor, and said one of the drain or the source of the partial transistor is a p-type region.

6. The apparatus of claim 4, further comprising:
a fifth transistor having a fifth transistor gate;
a sixth transistor having a sixth transistor gate;
a second partial transistor having a gate and only one of a drain or a source; and
a second gate interconnect connecting the fifth transistor gate to the sixth transistor gate through the gate of the second partial transistor.

7. The apparatus of claim 6, wherein the apparatus is a bit cell, a write word enable line comprises the second gate interconnect, and the fifth and sixth transistors enable a write bit lines to the bit cell.

8. The apparatus of claim 6, wherein the first inverter input and the second inverter output are connected to said one of the drain or the source of the second partial transistor.

9. The apparatus of claim 8, wherein the second inverter comprises a seventh transistor and an eighth transistor; the seventh transistor has a seventh transistor gate, a seventh transistor drain, and a seventh transistor source; the eighth transistor has an eighth transistor gate, an eighth transistor drain, and an eighth transistor source; the seventh transistor gate is connected to the eighth transistor gate; the seventh transistor drain is connected to the eighth transistor drain; the third transistor source is coupled to the seventh transistor source; the fourth transistor source is coupled to the eighth transistor source; the second inverter input is at the seventh transistor gate and the eighth transistor gate; the second inverter output is at the seventh transistor drain and the eighth transistor drain; and the seventh transistor drain is said one of the drain or the source of the second partial transistor.

10. The apparatus of claim 9, wherein the seventh transistor is a pMOS transistor, the eighth transistor is an nMOS transistor, and said one of the drain or the source of the second partial transistor is a p-type region.

11. A method of operating a complementary metal oxide semiconductor (CMOS) apparatus, comprising:
applying a voltage through a gate interconnect to a first transistor, a second transistor, and a partial transistor; and
turning on the first transistor and the second transistor through the gate interconnect based on the applied voltage, the first transistor having a first transistor gate, the second transistor having a second transistor gate, the gate interconnect connecting the first transistor gate to the second transistor gate through a gate of the partial transistor, the partial transistor having said gate and only one of a drain or a source, said voltage being applied to said gate of the partial transistor through the gate interconnect.

12. The method of claim 11, wherein the apparatus is a bit cell, a write word enable line comprises the gate interconnect, and the first and second transistors enable write bit lines to the bit cell when the first and second transistors are turned on.

13. The method of claim 11, wherein the apparatus includes a first inverter and a second inverter, the first inverter having a first inverter output and a first inverter input, the second inverter having a second inverter input and a second inverter output, the first inverter output being connected to the second inverter input, the first inverter input being connected to the second inverter output, the first inverter output and the second inverter input being connected to said one of the drain or the source of the partial transistor.

14. The method of claim 13, wherein the first inverter comprises a third transistor and a fourth transistor; the third transistor has a third transistor gate, a third transistor drain, and a third transistor source; the fourth transistor has a fourth transistor gate, a fourth transistor drain, and a fourth transistor source; the third transistor gate is connected to the fourth transistor gate; the third transistor drain is connected to the fourth transistor drain; the first inverter input is at the third transistor gate and the fourth transistor gate; the first inverter output is at the third transistor drain and the fourth transistor drain; and the third transistor drain is said one of the drain or the source of the partial transistor.

15. The method of claim 14, wherein the third transistor is a p-type metal oxide semiconductor (pMOS) transistor, the fourth transistor is an n-type metal oxide semiconductor (nMOS) transistor, and said one of the drain or the source of the partial transistor is a p-type region.

16. A complementary metal oxide semiconductor (CMOS) apparatus, comprising:
means for applying a voltage through a gate interconnect to a first transistor, a second transistor, and a partial transistor; and
means for turning on the first transistor and the second transistor through the gate interconnect based on the applied voltage, the first transistor having a first transistor gate, the second transistor having a second transistor gate, the gate interconnect connecting the first transistor gate to the second transistor gate through a gate of the partial transistor, the partial transistor having said gate and only one of a drain or a source, said voltage being applied to said gate of the partial transistor through the gate interconnect.

17. The apparatus of claim 16, wherein the apparatus is a bit cell, a write word enable line comprises the gate interconnect, and the first and second transistors enable write bit lines to the bit cell when the first and second transistors are turned on.

18. The apparatus of claim 16, wherein the apparatus includes a first inverter and a second inverter, the first inverter having a first inverter output and a first inverter input, the second inverter having a second inverter input and a second inverter output, the first inverter output being connected to the second inverter input, the first inverter input being connected to the second inverter output, the first inverter output and the second inverter input being connected to said one of the drain or the source of the partial transistor.

19. The apparatus of claim 18, wherein the first inverter comprises a third transistor and a fourth transistor; the third transistor has a third transistor gate, a third transistor drain, and a third transistor source; the fourth transistor has a fourth transistor gate, a fourth transistor drain, and a fourth transistor source; the third transistor gate is connected to the fourth transistor gate; the third transistor drain is connected to the fourth transistor drain; the first inverter input is at the third transistor gate and the fourth transistor gate;
the first inverter output is at the third transistor drain and the fourth transistor drain; and
the third transistor drain is said one of the drain or the source of the partial transistor.

20. The apparatus of claim 19, wherein the third transistor is a p-type metal oxide semiconductor (pMOS) transistor, the fourth transistor is an n-type metal oxide semiconductor (nMOS) transistor, and said one of the drain or the source of the partial transistor is a p-type region.
